(19) United States
(12) Patent Application Publication
(10) Pub. No.: US 2017/0278700 A1
(43) Pub. Date: Sep. 28, 2017

(54) TECHNIQUE FOR OXIDIZING PLASMA POST-TREATMENT FOR REDUCING PHOTOLITHOGRAPHY POISONING AND ASSOCIATED STRUCTURES

(71) Applicants: John D. Brooks, Hillsboro, OR (US); Sreenivas Kosaraju, Portland, OR (US); Pavel S. Plekhanov, Hillsboro, OR (US); Asad Iqbal, Portland, OR (US)

(72) Inventors: John D. Brooks, Hillsboro, OR (US); Sreenivas Kosaraju, Portland, OR (US); Pavel S. Plekhanov, Hillsboro, OR (US); Asad Iqbal, Portland, OR (US)

(21) Appl. No.: 15/504,005

(22) PCT Filed: Sep. 26, 2014
(86) PCT No.: PCT/US2014/057711

§ 371 Date: Feb. 14, 2017

(51) Int. Cl. H01L 21/02; H01L 21/311; H01L 21/768

(52) U.S. Cl. CPC H01L 21/0234; H01L 21/02329; H01L 21/02323; H01L 21/76826; H01L 21/31144; H01L 21/76834

(57) ABSTRACT

Embodiments of the present disclosure describe techniques for oxidizing plasma post-treatment for reducing photolithography poisoning. In one embodiment, an apparatus includes a dielectric layer with a plurality of routing features; and an etch stop layer, having a first interface region coupled with the dielectric layer and a second interface region disposed opposite to the first interface region. The first interface region has a peak silicon oxide (SiO₂) concentration level evenly distributed across the first interface region, and the second interface region has substantially zero silicon oxide (SiO₂) concentration level. Other embodiments may be described and/or claimed.

### FIELD

Embodiments of the present disclosure generally relate to the field of integrated circuits, and more particularly, to techniques for oxidizing plasma post-treatment for reducing photolithography poisoning and associated structures.

### BACKGROUND

In some patterning processes, photolithography steps may be executed after an etch stop (ES) layer is deposited to cap the metal lines. The chemistry from the ES layer may directly diffuse into the photolithography material to skew the size of patterned features, and/or skew etch rates in the development process. This poisoning effect may be presented in the post-patterning develop check critical dimension (DCCD) and/or final check critical dimension (FCCD) measurements.

The background description provided herein is for generally presenting the context of the disclosure. Unless otherwise indicated herein, the materials described in this section are not prior art to the claims in this application and are not admitted to be prior art or suggestions of the prior art, by inclusion in this section.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a top view of an example die in wafer form and in singulated form, in accordance with some embodiments.

FIG. 2 schematically illustrates a cross-section side view of an integrated circuit (IC) assembly, in accordance with some embodiments.

FIG. 3 schematically illustrates a cross-section side view of interconnect layers of an IC device, in accordance with some embodiments.

FIG. 4 schematically illustrates a flow diagram for a method of oxidizing plasma post-treatment, in accordance with some embodiments.

FIG. 5 schematically illustrates depth profiles for SiO₂ and SiN at various sites on a wafer, in accordance with some embodiments.

FIG. 6 schematically illustrates an example system that may include a transistor contact assembly as described herein, in accordance with some embodiments.

### DETAILED DESCRIPTION

Embodiments of the present disclosure describe techniques for oxidizing plasma post-treatment for reducing photolithography poisoning and associated structures. in the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, side, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

As used herein, the term “module” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable components that provide the described functionality.

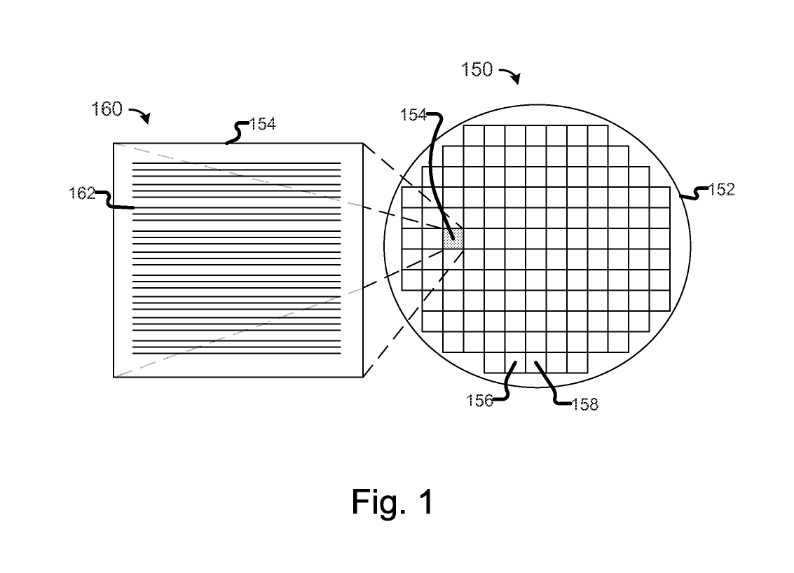

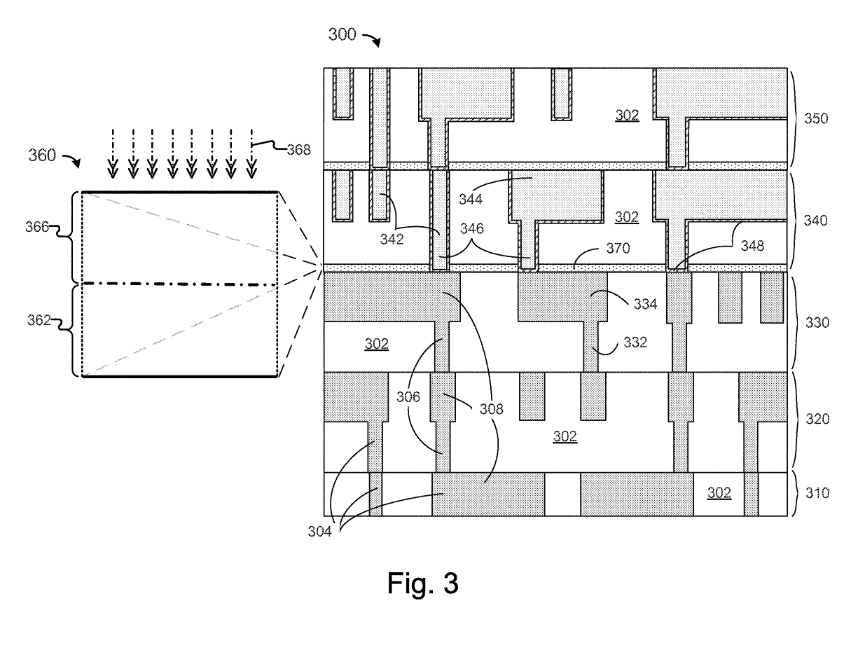

FIG. 1 schematically illustrates a top view of an example die 154 in wafer form 150 and in singulated form 160, in accordance with some embodiments. In sonic embodiments, the die 154 may be one of a plurality of dies (e.g., dies 154, 156, 158) of a wafer 152 composed of semiconductor material such as, for example, silicon or other suitable material, The plurality of dies may be formed on a surface of the wafer 152, Each of the dies may be a repeating unit of a semiconductor product that includes one or more routing features (e.g., various vias and trenches of FIG. 3) as described herein. For example, the die 154 may include circuitry having transistor structures 162 such as, for example, one or more channel bodies (e.g., fin structures, nanowires, planar bodies, etc.) that provide a channel pathway for mobile charge carriers of one or more transistor devices or source/drain regions.

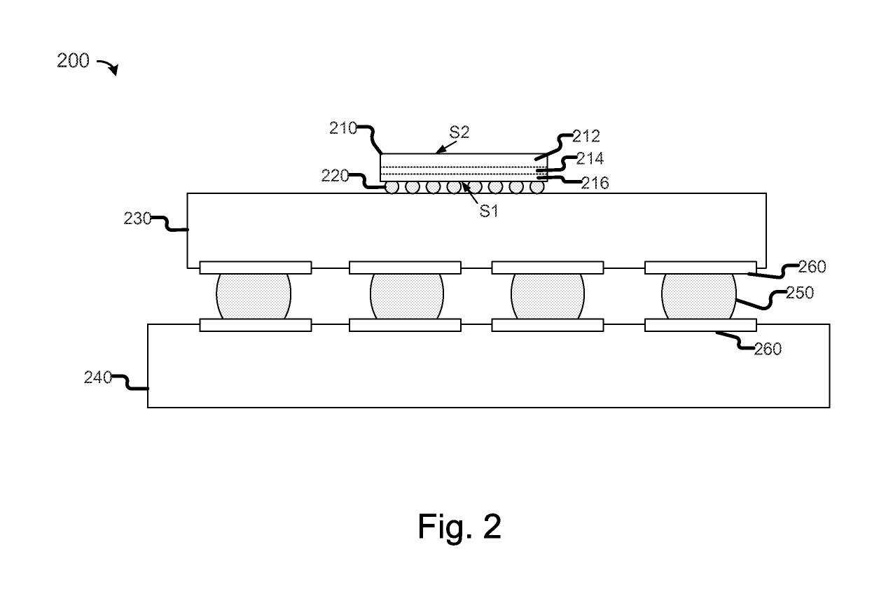

Electrical interconnect structures such as, for example, terminal contacts, trenches and/or vias may be formed on and coupled with the one or more transistor structures 162 to route electrical energy to or from the transistor structures 162. For example, the interconnect structures may be electrically coupled with a channel body to provide a gate electrode for delivery of a threshold voltage and/or a source/drain current to provide mobile charge carriers for operation of a transistor device. The interconnect structures may, for example, be disposed in interconnect layer 216 of FIG. 2. Although the transistor structures 162 are depicted in rows that traverse a substantial portion of the die 154 in FIG. 1 for the sake of simplicity, it is to be understood that the transistor structures 162 may be configured in any of a wide variety of other suitable arrangements on the die 154 in other embodiments, including, for example, vertical and horizontal features having much smaller dimensions than depicted.

After a fabrication process of the semiconductor product embodied in the dies is complete, the wafer 152 may undergo a singulation process in which each of the dies (e.g., die 154) is separated from one another to provide discrete “chips” of the semiconductor product. The wafer 152 may be any of a variety of sizes. In some embodiments, the wafer 152 has a diameter ranging front about 25.4 mm to about 450 mm. The wafer 152 may include other sizes and/or other shapes in other embodiments. According to various embodiments, the transistor structures 162 may be disposed on a semiconductor substrate in wafer form 150 or singulated form 160. The transistor structures 162 described herein may be incorporated in a die 154 for logic or memory, or combinations thereof. In some embodiments, the transistor structures 162 may be part of a system-on-chip (SoC) assembly.

FIG. 2 schematically illustrates a cross-section side view of an integrated circuit (IC) assembly 200, in accordance with some embodiments. In some embodiments, the IC assembly 200 may include one or more dies (hereinafter “die 210”) electrically and/or physically coupled with a package substrate 230. In some embodiments, the die 210 may comport with embodiments described in connection with the die 154 of FIG. 1. in some embodiments, the package substrate 230 may be electrically coupled with a circuit board 240, as can be seen. In some embodiments, an integrated circuit (IC) assembly 200 may include one or more of the die 154, package substrate 230 and/or circuit board 240, according to various embodiments. Embodiments described herein for techniques for oxidizing plasma post-treatment for reducing photolithography poisoning and associated structures may be implemented in any suitable IC device according to various embodiments.

The die 210 may represent a discrete product made from a semiconductor material (e.g., silicon) using semiconductor fabrication techniques such as thin film deposition, lithography, etching and the like used in connection with forming complementary metal-oxide semiconductor (CMOS) devices. In some embodiments, the die 210 may be, include, or be a part of a processor, memory, SoC, or ASIC. In some embodiments, an electrically insulative material such as, for example, molding compound or underfill material (not shown) may encapsulate at least a portion of the die 210 and/or die-level interconnect structures 220.

The die 210 can be attached to the package substrate 230 according to a wide variety of suitable configurations including, for example, being directly coupled with the package substrate 230 in a flip-chip configuration, as depicted. In the flip-chip configuration, an active side, S1, of the die 210 including circuitry is attached to a surface of the package substrate 230 using die-level interconnect structures 220 such as bumps, pillars, or other suitable structures that may also electrically couple the die 210 with the package substrate 230. The active side S1 of the die 210 may include active devices such as, for example, transistor devices. An inactive side, S2, may be disposed opposite to the active side S1, as can be seen.

The die 210 may generally include a semiconductor substrate 212, one or more device layers (hereinafter “device layer 214”), and one or more interconnect layers (hereinafter “interconnect layer 216”). The semiconductor substrate 212 may be substantially composed of a bulk semiconductor material such as, for example, silicon, in Wale embodiments. The device layer 214 may represent a region where active devices such as transistor devices are formed on the semiconductor substrate. The device layer 214 may include, for example, transistor structures such as channel bodies and/or source/drain regions of transistor devices. The interconnect layer 216 may include interconnect structures (e.g., electrode terminals) that are configured to route electrical signals to or from the active devices in the device layer 214. For example, the interconnect layer 216 may include horizontal lines (e.g., trenches) and/or vertical plugs (e.g., vias) or other suitable features to provide electrical routing and/or contacts.

In some embodiments, the die-level interconnect structures 220 may be electrically coupled with the interconnect layer 216 and configured to route electrical signals between the die 210 and other electrical devices. The electrical signals may include, for example, input/output (I/O) signals and/or power/ground signals that are used in connection with operation of the die 210.

In some embodiments, the package substrate 230 is an epoxy-based laminate substrate having a core and/or build-up layers such as, for example, an Ajinomoto Build-up Film (ABF) substrate. The package substrate 230 may include other suitable types of substrates in other embodiments including, for example, substrates formed from glass, ceramic, or semiconductor materials.

The package substrate 230 may include electrical routing features configured to route electrical signals to or from the die 210. The electrical routing features may include, for example, pads or traces (not shown) disposed on one or more surfaces of the package substrate 230 and/or internal routing features (not shown) such as, for example, trenches, vias, or other interconnect structures to route electrical signals through the package substrate 230. For example, in some embodiments, the package substrate 230 may include electrical routing features such as pads (not shown) configured to receive the respective die-level interconnect structures 220 of the die 210.

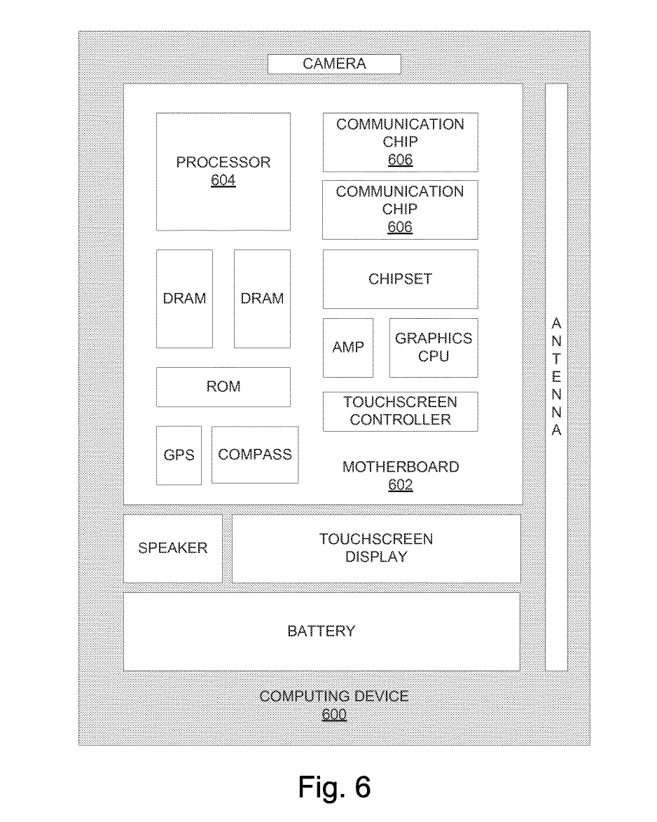

The circuit board 240 may be a printed circuit board (PCB) composed of an electrically insulative material such as an epoxy laminate. For example, the circuit board 240 may include electrically insulating layers composed of materials such as, for example, polytetrafluoroethylene, phenolic cotton paper materials such as Flame Retardant 4 (FR-4), FR-1, cotton paper and epoxy materials such as CEM-1 or CEM-3, or woven glass materials that are laminated together using an epoxy resin prepreg material. Interconnect structures (not shown) such as traces, trenches, or vias may be formed through the electrically insulating layers to route the electrical signals of the die 210 through the circuit board 240. The circuit board 240 may be composed of other suitable materials in other embodiments. In some embodiments, the circuit board 240 is a motherboard (e.g., motherboard 602 of FIG. 6).

Package-level interconnects such as, for example, solder balls 250 may be coupled to one or more pads (hereinafter “pads 260”) on the package substrate 230 and/or on the circuit board 240 to form corresponding solder joints that are configured to further route the electrical signals between the package substrate 230 and the circuit board 240. The pads 260 may be composed of any suitable electrically conductive material such as metal, including, for example, nickel (Ni), palladium (Pd), gold (Au), silver (Ag), copper (Cu), and combinations thereof. Other suitable techniques to physically and/or electrically couple the package substrate 230 with the circuit board 240 may be used in other embodiments.

The IC assembly 200 may include a wide variety of other suitable configurations in other embodiments, including, for example, suitable combinations of flip-chip and/or wire-bonding configurations, interposers, and multi-chip package configurations including system-in-package (SiP) and/or package-on-package (PoP) configurations. Other suitable techniques to route electrical signals between the die 210 and other components of the IC assembly 200 may be used in some embodiments.

FIG. 3 schematically illustrates a cross-section side view of interconnect layers 310, 320, 330, 340, and 350 of an IC device 300, in accordance with some embodiments. In some embodiments, the interconnect layers 310, 320, 330, 340. or 350 of the IC device 300 may be part of the interconnect layer 216 of FIG. 2. In various embodiments, the interconnect layers may include various interconnect structures, which may be composed of an electrically conductive material including metal such as, for example, copper or aluminum.

In some embodiments, the interconnect structures 304 may include trench structures 308 (sometimes referred to as “lines”) and/or via structures 306 (sometimes referred to as “holes”) filled with an electrically conductive material such as, for example, copper. The interconnect structures 304 may be interlayer interconnects that provide routing of electrical signals through a stack of interconnect layers.

In some embodiments, the trench structures 308 may be configured to route electrical signals in a direction of a plane that is substantially parallel with an interconnect layer, e.g., the interconnect layer 310. For example, the trench structures 308 may route electrical signals in a direction in and out of the page in the perspective of FIG. 3, in some embodiments. The via structures 306 may be configured to route electrical signals in a direction of a plane that is substantially perpendicular with the trench structures 308. In some embodiments, the via structures 306 may electrically couple trench structures 308 of different interconnect layers 320 and 330 together.

The interconnect layers 310, 320, 330, 340, and 350 may include a dielectric material 302 disposed between the interconnect structures 304, as can be seen. The dielectric material 302 may include any of a wide variety of suitable electrically insulative materials including, for example interlayer dielectric (ILD) materials. The dielectric material 302 may be formed using dielectric materials known for their applicability in integrated circuit structures, such as low-k dielectric materials. Examples of dielectric materials that may be used include, but are not limited to, silicon oxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The dielectric material 302 may include pores or other voids to further reduce their dielectric constant. The dielectric material 302 may include other suitable materials in other embodiments.

In some embodiments, the interconnect layers 310, 320, 330, 340, or 350 may include a barrier liner 348. In some embodiments, the barrier liner 348 may be disposed between metal of the interconnect structures 304 and the dielectric material 302. and/or between the metal of adjacent interconnect structures 304 of different interconnect layers (e.g., interconnect layers 330, 340), as can be seen. In some embodiments, the barrier liner 348 may be composed of a material other than Cu such as, for example, tantalum (Ta), titanium (Ti), or tungsten (W). In some embodiments, the barrier liner 348 may include tantalum nitride (MN). The barrier liner 348 may include other suitable materials in other embodiments.

The interconnect layer 340 may include a hermetic dielectric layer 370 that is configured to prevent oxidation or other corrosion of features in the underlying layers. The hermetic dielectric layer 370 may be disposed between dielectric material 302 that forms a dielectric layer of the interconnect layer 340 and dielectric material 302 that forms a dielectric layer of the interconnect layer 330. The hermetic dielectric layer 370 may have a different chemical composition than the dielectric material 302. In some embodiments, the hermetic dielectric layer 370 may be composed of silicon nitride (SiN), silicon carbide (SiC), silicon oxynitride, carbon doped silicon nitride, carbon doped silicon oxynitride, etc. The hermetic dielectric layer 370 may have a thickness that is smaller than a thickness of the dielectric material 302. Other interconnect layers similarly configured as the interconnect layer 340 may be stacked on the interconnect layer 340 in various embodiments.

In various embodiments, the hermetic dielectric layer 370 may also be known as an etch stop (ES) layer 370 or the capping layer in a damascene process, in which via structures and trench structures may be fabricated at the same time. In various embodiments, an oxidizing plasma post-treatment may be applied to the ES layer 370 for reducing photolithography poisoning effect to the interconnect layer 340. A segment 360 of the ES layer 370 is enlarged to show different regions within the ES layer 370. In sonic embodiments, the ES layer 370 may have a first interface region 362 coupled with the interconnect layer 330 and a second interface region 366 coupled with the interconnect layer 340. In various embodiments, the second interface region 366 may receive a post-treatment based on the oxidizing plasma 368 before further building up the interconnect layer 340.

The interconnect structures 304, 306, 308, 332, 334, 342, 344, or 346 may be configured within the interconnect layers 310, 320, 330, 340, or 350 to route electrical signals according to a wide variety of designs and are not limited to the particular configuration of interconnect structures depicted in FIG. 3. Although particular interconnect layers 310, 320, 330, 340, and 350 are depicted in FIG. 3, embodiments of the present disclosure include IC devices having more or fewer interconnect layers than depicted.

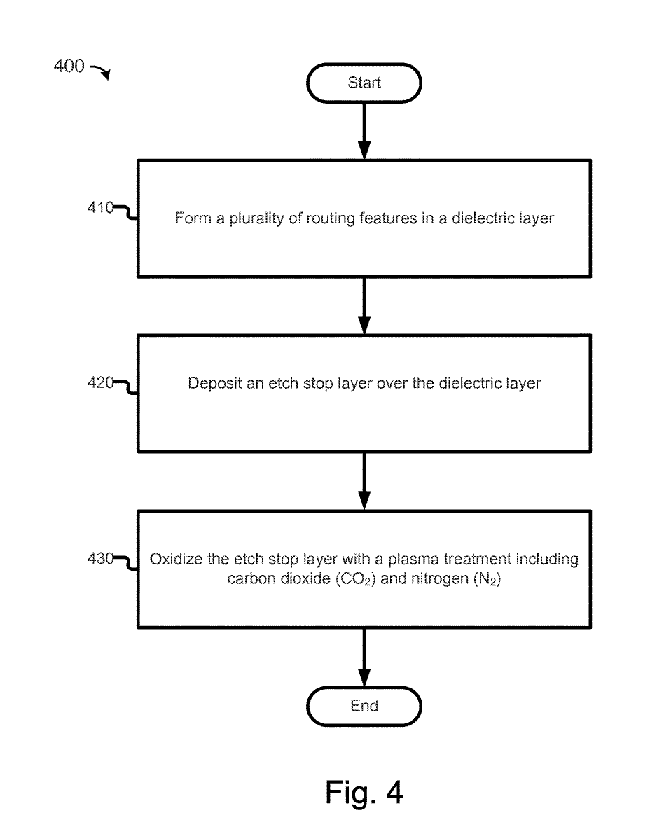

FIG. 4 schematically illustrates a flow diagram for a process 400 of oxidizing plasma post-treatment (e.g., applied to the etch stop layer 370 of FIG. 3), in accordance with some embodiments. The process 400 may comport with embodiments described in connection with FIGS. 1-3 and vice versa.

At 410, the process 400 may include forming a plurality of routing features in a dielectric layer. In some embodiments, forming the plurality of routing features comprises forming a plurality of vias and trenches in a dual-damascene process. As an example, in connection with FIG. 3, the routing features, e.g., the via 332 and the trench 334, may be fabricated in a dual-damascene process. The damascene process may start with forming the vacant pattern of the via 332 and the trench 334 on the interconnect layer 330, e.g., by depositing and patterning using lithography and etching techniques on the dielectric material 302. Next, a diffusion barrier (e.g., based on Tantalum (Ta), not shown) may be deposited to the vacant pattern of the via 332 and the trench 334. The diffusion barrier may improve Cu adhesion and prevent Cu atoms from migrating into the ILD. Next, a thin Cu seed (not shown) may be deposited after the deposition of the diffusion barrier, e.g., by physical vapor deposition (PVD). Next, a selected metal, e.g., Cu, may be used to fill the pattern of the via 332 and the trench 334, e.g., by the electroplating of the metal.

At 420, the process 400 may include depositing an etch stop layer over the dielectric layer. In various embodiments, after removing any excess metal (e.g., Cu) from previously formed routing features, e.g., by a chemical mechanical polishing process (CMP), an ES layer (e.g., the ES layer 370 of FIG. 3) may be formed, e.g., by deposition, over the underlying dielectric layer (e.g., the interconnect layer 330 of FIG. 3). The ES layer may be composed of silicon nitride (SiN), silicon carbide (SiC), silicon oxynitride, carbon doped silicon nitride, carbon doped silicon oxynitride, etc., in various embodiments.

The ES layer may protect the underlying interconnect structures, e.g., the via 332 and the trench 334 of FIG. 3, during etching of the overlying dielectric layers, e.g., the interconnect layer 340 of FIG. 3. In some embodiments, the ES layer may also serve as a diffusion barrier. In some embodiments, the ES layer may also serve as an anti-reflective coating (ARC) to facilitate the formation of the via structures.

At 430, the process 400 may include oxidizing the etch stop layer with a plasma treatment including carbon dioxide (CO₂) and nitrogen (N₂) (“CO₂/N₂ plasma,” hereinafter). In various embodiments, the oxidizing plasma post-treatment with the CO₂/N₇ plasma may oxidize the surface of the ES layer (e.g., the second region 366) without altering the bulk ES film properties, e.g., for the first region 362. Thus, the ES layer may retain its properties, such as hermiticity, conformality, dielectric constant, etc.

As an example, in connection with FIG. 3, the oxidizing plasma 368 may be applied to the ES layer 370, e.g., in a plasma enhanced chemical vapor deposition (PECVD) process. The oxidizing plasma 368 may oxidize the second interface region 366 with the effect of stripping photolithography impactful chemistry from the second interface region 366 of the ES layer 370.

In some embodiments, N₂O/O₂, plasma may be used. While the N₂O/O₂ plasma may be effective, it may pose a safety risk in a process chamber plumbed with H₂ source. However, CO² is known to be H₂ compatible; therefore, CO₂/N₂ plasma post-treatment is safer even in a system plumbed with H₂ source during the PECVD process. Further, N₂ gas in the oxidizing plasma may drive ion penetration deeper into the ES layer. Therefore, the CO₂/N₂ plasma is a safer solution in amine driven patterning processes for reducing photolithography poisoning effect.

In various embodiments, the CO₂/N₂ plasma post-treatment may cause significant SiN reduction and SiO increase on the surface region of the ES layer, thus reducing photolithography poisoning. For example, a reduced SiN peak as well as an increased SiO peak may be observed in a fourier transform infrared spectroscopy (FTIR) spectrum after the CO₂/N₂ plasma post-treatment.

In various embodiments, the role of N₂ gas in the oxidizing plasma may include driving ion penetration deeper into the film, and modulating the Within Wafer (WIW) ion profile. In some embodiments, without N₂, the plasma may oxidize the edge of a wafer, but the effectiveness of such treatment at the center of the wafer is very limited. Increasing N₂ increases effectiveness at the center of the wafer, and also drives the ions deeper into film. Hence, the N₂ gas may increase the overall signal intensity as well as improve the WIW oxidization uniformity.

In some embodiments, a ratio of carbon dioxide (CO₂) to nitrogen (N₂) between 9:2 and. 1:1 in the CO₂/N₂ plasma may be used to oxidize the etch stop layer for a wafer. In some embodiments, a ratio of carbon dioxide (CO₂) to nitrogen (N₂) between 3:1 and 4:1 in the CO₂/N₂ plasma may uniformly oxidize the etch stop layer for a wafer. As an example, a CO₂/N₂ plasma with 3000 standard cubic centimeter per minute (SCCM) N₂ joined with 9000 SCCM CO₂ may maintain suitable momentum to penetrate the ES layer and uniformly oxidize the ES layer on the wafer, but array not invade too deep into the ES layer to alter the basic properties of the ES layer. With the CO₂/N₂ plasma post-treatment, not only may the photolithography poisoning effect reduced, but the WIW ion profile may also become more consistent. Further, bulk film properties of the ES layer may be tuned to meet other important film characteristics, such as hermiticity, low-k, etch stop ability, etc.

In various embodiments, the process 400 may be repeated to build up more layers with different patterns of interconnect structures. Various operations are described as multiple discrete operations in turn, in a manner that is most helpful in understanding the claimed subject matter. However, the order of description should not be construed as to imply that these operations are necessarily order dependent. Further, embodiments of the present disclosure may be implemented into a system using any suitable hardware and/or software to configure as desired.

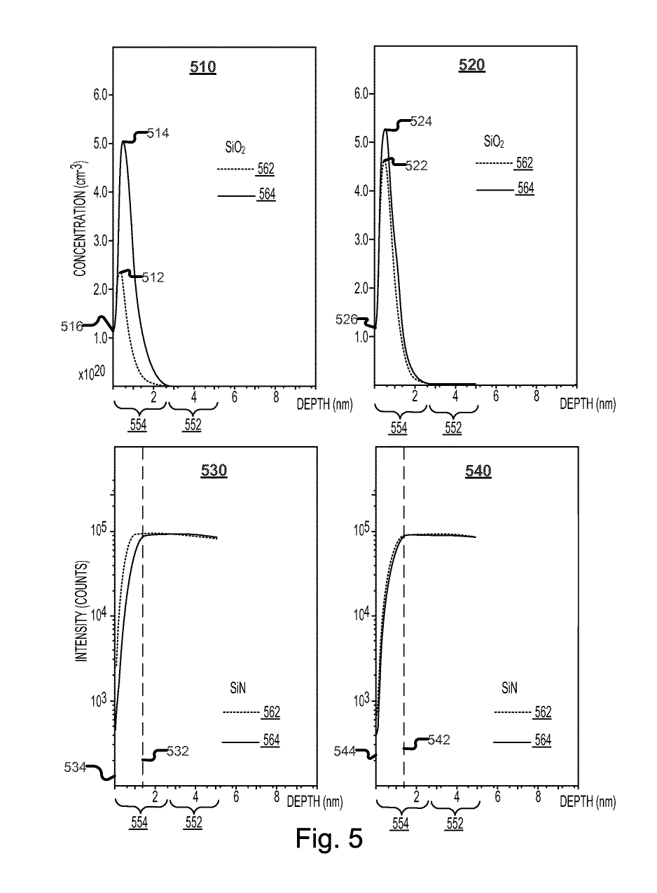

FIG. 5 schematically illustrates depth profiles for SiO₂ and SiN at various sites on a wafer, in accordance with some embodiments. After oxidizing the ES layer with a plasma post-treatment including carbon dioxide (CO₂) and nitrogen (N₂), Time-of-Flight Secondary Ion Mass Spectrometry (TOF-SIMS) sputter depth profiles may be used to show various changes at the ES layer. For examples, depth profiles (DP) 510 shows the TOF-SIMS sputter depth profile of SiO₂ at the center of a wafer, and DP 520 shows the TOE-SIMS sputter depth profile of SiO₂ at the edge of the wafer. Similarly, DP 530 shows the TOF-SIMS sputter depth profile of SiN at the center of the wafer, and DP 540 shows the TOF-SIMS sputter depth profile of SiN at the edge of the wafer.

DP 510, 520, 530, or 540 demonstrates the distribution of different chemical species (e.g., SiO₂SiN) as a function of depth from the wafer surface. A pulsed ion beam (e.g., Cesium (Cs) or Gallium (Ga)) may be used in TOE-SIMS to dislodge and ionize species from a sample surface of a wafer. The particles removed from the sample surface (e.g., the secondary ions) may be accelerated into a mass spectrometer. The mass of such particles may then be determined based on their time-of-flight from the sample surface to the detector. Therefore, a particular chemical (e.g., SiO₂ or SiN) may be ascertained from the secondary ions, and DP 510, 520, 530, or 540 may show the chemical stratigraphy on the wafer after sequential sputtering of its surfaces.

DP 510 includes results from two experiments. Experiment 562 represents the DP of SiO₂ or SiN on a wafer after a plasma post-treatment including carbon dioxide (CO2) but excluding nitrogen (N₂). On the other hand, experiment 564 represents the DP of SiO₂ or SiN on a wafer after a CO₂/N₂ plasma post-treatment, e.g., as described in 430 of FIG. 4. Both experiments reveal different manifestations of SiO₂ or SiN in different regions of the wafer, such as the first region 552 and the second region 554. In various embodiments, regions 552 and 554 may respectively comport with the regions 362 and 366 of FIG. 3.

Shown in DP 510, experiment 562 produces a peak concentration level (PCL) 512 of silicon oxide (SiO₂) at the second region 554. Similarly, experiment 564 produces another PCL 514 of silicon oxide (SiO₂) at the second region 554. PCL 512 and PCL 514 both demonstrate that the oxidizing plasma post-treatment has been applied to the second region 554, not the first region 552. Further, shown in DP 510, there is no silicon oxide (SiO₂) at the first region 552, which demonstrates that the oxidizing plasma is attenuated by the hulk film and only shows impact on top region of the film exposed directly to the treatment. Thus, at least the bulk film composition at the first region 552 is not impacted by the treatment.

Further, it may be noted that the concentration of SiO₂ at the outermost surface of the second region 554 is already at an observable level 516 (e.g., compared to the substantially zero concentration of SiO₂ at the first region 552), which may evidence the efficacy of the oxidizing plasma post-treatment in general. Additionally, the PCL 514 is greater than the PCL level 512 by a factor of two or more, which may evidence the efficacy of the CO₂/N₂ plasma post-treatment in particular, e.g., compared to the oxidizing plasma post treatment without N₂. Such difference may be caused by the efficacy of N₂ lo drive deeper into the wafer in the CO₂/N₂ plasma post-treatment.

Shown in DP 520, the experiment 562 produces a PCL 522 of SiO₂ at the second region 554. Similarly, experiment 564 produces a PCL 524 of SiO₂ at the second region 554. Compared to their counterparts in DP 510, the experiment 562 without N₂ demonstrates a discrepancy of oxidization between the center site and the edge site of the wafer. However, the experiment 564 with the CO₂/N₂ plasma post-treatment demonstrates a general uniformity of oxidization between the center site and the edge site.

Shown in DP 530, both experiment 562 and experiment 564 show that the concentration of SiN at the outermost surface 534 of the second region 554 is at the lowest concentration level in the ES layer. Thereafter, the concentration of SiN increases across the second region 554 to a peak level around the depth 532, and thereafter it becomes substantially constant. The increasing SiN concentration profile from the outermost surface 534 of the etch stop layer in DP 530 may evidence the efficacy of the oxidizing plasma post-treatment in general to drive out photolithography poisoning chemicals (e.g., amines, including SiN) from the second region 554, which receives the oxidizing plasma. Therefore, the poisoning effect of the etch stop layer may be decreased during subsequent lithography processing.

DP 540 may exemplify the similar effect that SiN has been largely driven out from the outermost surface 544 up to the depth 542. Combining DP 530 and DP 510, it may be evident that the oxidizing plasma post-treatment may convert SiN to SiO₂ at an outermost region of the ES layer, such as in the second region 554, but not further deep into the ES layer, such as the first region 552.

FIG. 6 schematically illustrates an example system (e.g., computing device 600) that may include an IC device (e.g., IC device 300 of FIG. 3) having an ES layer (e.g., ES layer 370 of FIG. 3) as described herein, in accordance with sonic embodiments. Components of the computing device 600 may be housed in an enclosure (not shown). The motherboard 602 may include a number of components, including but not limited to a processor 604 and at least one communication chip 606. The processor 604 may be physically and electrically coupled to the motherboard 602. In some implementations, the at least one communication chip 606 may also be physically and electrically coupled to the motherboard 602. In further implementations, the communication chip 606 may be part of the processor 604.

Depending on its applications, computing device 600 may include other components that may or may not be physically and electrically coupled to the motherboard 602. These other components may include, but are not limited to, volatile memory (e.g., dynamic random-access memory (DRAM)), non-volatile memory (e.g., read-only memory (ROM)), flash memory, a graphics processor, a digital signal processor, a crypto processor, a chipset, an antenna, a display, a touchscrecn display, a touchscrecn controller, a battery, an audio codec, a video codec, a power amplifier, a global positioning system (GPS) device, a compass, a Geiger counter, an accelerometer, a gyroscope, a speaker, a camera, and a class storage device (such as hard disk drive, compact disk (CD), digital versatile disk (DVD), and so forth).

The communication chip 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to institute for Electrical and Electronic Engineers (IEEE) standards including (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible broadband wireless access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 606 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 606 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 606 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 606 may operate in accordance with other wireless protocols in other embodiments.

The computing device 600 may include a plurality of communication chips 606. For instance, a first communication chip 606 may be dedicated to shorter range wireless communications such as Wi-Fi and Bluetooth, and a second communication chip 606 may be dedicated to longer range wireless communications such as GPS, EDGE, GPRS, CDMA, WiMAX, LTE, EV-DO, and others.

The processor 604 of the computing device 600 may include a die (e.g., die 210 of FIG. 2) having at least one ES layer (e.g., ES layer 370 of FIG. 3) oxidized using a CO₂/N₂ plasma post-treatment for reducing photolithography poisoning The die 210 may be mounted in a package assembly that is mounted on a circuit board such as the motherboard 602. The term “processor” may refer to any device or portion of a device that processes electronic data from registers and/or memory to transform that electronic data into other electronic data that may be stored in registers and/or memory.

The communication chip 606 may also include a die (e.g., die 210 of FIG. 2) having at least one ES layer (e.g., ES layer 370 of FIG. 3) oxidized using a CO₂/N₂ plasma post-treatment for reducing photolithography poisoning as described herein. In further implementations, another component (e.g., memory device or other integrated circuit device) housed within the computing device 600 may also contain a die (e.g., die 210 of FIG. 2) having at least one ES layer (e.g., ES layer 370 of FIG. 3) oxidized using a CO₇/N₂ plasma post-treatment for reducing photolithography poisoning as described herein.

In various implementations, the computing device 600 may be a mobile computing device, a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

### EXAMPLES

According to various embodiments, the present disclosure describes an apparatus (e.g., including an integrated circuit (IC) structure). Example 1 of an apparatus may include a dielectric layer with a plurality of routing features; and an etch stop layer, having a first interface region coupled with the dielectric layer and a second interface region disposed opposite to the first interface region; wherein the first interface region has a peak silicon oxide (SiO₂) concentration level evenly distributed across the first interface region, and the second interface region has substantially zero silicon oxide (SiO₂) concentration level.

Example 2 may include the apparatus of Example 1, wherein the peak silicon oxide (SiO₂) concentration level is at least 3×10²⁰ atoms per cubic centimeters. Example 3 may include the apparatus of Example 1 or 2, wherein the peak silicon oxide (SiO₂) concentration level is at least 4×10²⁰ atoms per cubic centimeters, Example 4 may include the apparatus of any of Examples 1-3, wherein a concentration of SiN at a outermost surface of the second interface region is a lowest concentration of SiN in the etch stop layer; and wherein the concentration of SiN increases in the second interface region to a peak level and is substantially constant across the first region.

Example 5 may include the apparatus of any of Examples 1-4, wherein a profile of SiO₂ concentration levels in the first interface region and the second interface region is consistent with the etch stop layer being treated by a plasma treatment including carbon dioxide (CO₂) and nitrogen (N₂)) from the second interface region. Example 6 may include the apparatus of any of Examples 1-5, wherein the dielectric layer is a first dielectric layer, the apparatus further includes a semiconductor substrate of a die or wafer, wherein the first dielectric layer is disposed on the semiconductor substrate; and a second dielectric layer coupled with the second interface region of the first dielectric layer.

Example 7 may include the apparatus of any of Examples 1-6, wherein the first interface region and the second interface region have a same thickness. Example 8 may include the apparatus of any of Examples 1-7, wherein the plurality of routing features comprises a plurality of vias and trenches, and wherein the etch stop layer is an etch stop layer having silicon carbide (SiC).

According to various embodiments, the present disclosure describes a method (e.g., of fabricating an IC structure). Example 9 of a method may include forming a plurality of routing features in a dielectric layer; depositing an etch stop layer over the dielectric layer; and oxidizing the etch stop layer with a plasma treatment including carbon dioxide (CO₂) and nitrogen (N₂).

Example 10 may include the method of Example 9, wherein forming the plurality of routing features comprises forming a plurality of vias and trenches in a dual-damascene process. Example 11 may include the method of Example 9 or 10, wherein depositing the etch stop layer comprises depositing silicon carbide (SiC). Example 12 may include the method of any of Examples 9-11, wherein oxidizing the etch stop layer comprises using a ratio of carbon dioxide (CO₂) to nitrogen (N₂) between 3:1 and 4:1 for the plasma treatment. Example 13 may include the method of any of Examples 9-12, wherein oxidizing the etch stop layer comprises converting SiN to SiO₂ only at an outermost region of the etch stop layer. Example 14 may include the method of any of Examples 9-13, wherein oxidizing the etch stop layer comprises producing a peak SiO₂ concentration level only at one surface of the etch stop layer.

Example 15 may include the method of any of Examples 9-14, wherein oxidizing the etch stop layer comprises producing an SiN concentration profile increasing from a surface of the etch stop layer. Example 16 may include the method of Example 15, wherein the SiN concentration profile reaches a peak level, and substantially maintains the peak level in a direction towards an opposing surface of the etch stop layer. Example 17 may include the method of any of Examples 9-16, wherein oxidizing the etch stop layer comprises decreasing a poisoning effect of the etch stop layer during subsequent lithography processing. Example 18 may include the method of any of Examples 9-17, wherein the oxidizing is executed in a plasma enhanced chemical vapor deposition (PECVD) process. Example 19 may include the method of any of Examples 9-17, wherein the oxidizing is executed in a plasma enhanced chemical vapor deposition (PECVD) process chamber having hydrogen (H₂).

Example 20 is at least one storage medium having instructions configured to cause an apparatus, in response to execution of the instructions by the apparatus, to practice any subject matter of methods 9-19. Example 21 is an apparatus for fabricating an integrated circuit (IC) structure, which may include means to practice any subject matter of methods 9-19.

According to various embodiments, the present disclosure describes a system (e.g., a computing device). Example 22 of a computing device may include a circuit board; and a die electrically coupled with the circuit board, the die including a dielectric layer with a plurality of routing features; and an etch stop layer, having a first interface region coupled with the dielectric layer and a second interface region disposed opposite to the first interface region; wherein a profile of SiO₂ concentration levels in the first interface region and the second interface region is consistent with the etch slop layer being treated by a plasma treatment including carbon dioxide (CO₂) and nitrogen (N₂) from the second interface region.

Example 23 may include the system of Example 22, wherein the first interface region has a peak silicon oxide (SiO₂) concentration level evenly distributed across the etch stop layer, and the second interface region has substantially zero silicon oxide (SiO₂) concentration level. Example 24 may include the system of Example 22 or 23, wherein a concentration of SiN at an outermost surface of the second interface region is a lowest concentration of SiN in the etch stop layer; and wherein the concentration of SiN increases continuously in the second region to a peak level and is substantially constant across the first region. Example 25 may include the computing device of any of Examples 22-24, wherein the die is a processor; and the system is a mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, and a camera.

Various embodiments may include any suitable combination of the above-described embodiments including alternative (or) embodiments of embodiments that are described in conjunctive form (and) above (e.g., the “and” may be “and/or”). Furthermore, sonic embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

1. An apparatus, comprising:
a dielectric layer with a plurality of routing features; and
an etch stop layer, having a first interface region coupled with the dielectric layer and a second interface region disposed opposite to the first interface region;
wherein the first interface region has a peak silicon oxide (SiO₂) concentration level evenly distributed across the first interface region, and the second interface region has substantially zero silicon oxide (SiO₂) concentration level.

2. The apparatus of claim 1, wherein the peak silicon oxide (SiO₂) concentration level is at least 3×10²⁰ atoms per cubic centimeters.

3. The apparatus of claim 1, wherein the peak silicon oxide (SiO₂) concentration level is at least 4×10²⁰ atoms per cubic centimeters.

4. The apparatus of claim 1, wherein a concentration of SiN at a outermost surface of the second interface region is a lowest concentration of SiN in the etch stop layer; and wherein the concentration of SiN increases in the second interface region to a peak level and is substantially constant across the first region.

5. The apparatus of claim 1, wherein a profile of SiO₂ concentration levels in the first interface region and the second interface region is consistent with the etch stop layer being treated by a plasma treatment including carbon dioxide (CO₂) and nitrogen (N₂) from the second interface region.

6. The apparatus of claim 1, wherein the dielectric layer is a first dielectric layer, the apparatus further comprising:
a semiconductor substrate of a die or wafer, wherein the first dielectric layer is disposed on the semiconductor substrate; and
a second dielectric layer coupled with the second interface region of the first dielectric layer.

7. The apparatus of claim 1, wherein the first interface region and the second interface region have a same thickness.

8. The apparatus of claim 1, wherein the plurality of routing features comprises a plurality of vias and trenches, and wherein the etch stop layer is an etch stop layer having silicon carbide (SiC).

9. A method, comprising:
forming a plurality of routing features in a dielectric layer;
depositing an etch stop layer over the dielectric layer; and
oxidizing the etch stop layer with a plasma treatment including carbon dioxide (CO₂) and nitrogen (N₂).

10. The method of claim 9, wherein forming the plurality of routing features comprises forming a plurality of vias and trenches in a dual-damascene process.

11. The method of claim 9, wherein depositing the etch stop layer comprises depositing silicon carbide (SiC).

12. The method of claim 9, wherein oxidizing the etch stop layer comprises using a ratio of carbon dioxide (CO₂) to nitrogen (N₂) between 3:1 and 4:1 for the plasma treatment.

13. The method of claim 9, wherein oxidizing the etch stop layer comprises converting SiN to SiO₂ only at an outermost region of the etch stop layer.

14. The method of claim 9, wherein oxidizing the etch stop layer comprises producing a peak SiO₂ concentration level only at one surface of the etch stop layer.

15. The method of claim 9, wherein oxidizing the etch stop layer comprises producing an SiN concentration profile increasing from a surface of the etch stop layer.

16. The method of claim 15, wherein the SiN concentration profile reaches a peak level, and substantially maintains the peak level in a direction towards an opposing surface of the etch stop layer.

17. The method of claim 9, wherein oxidizing the etch stop layer comprises decreasing a poisoning effect of the etch stop layer during subsequent lithography processing.

18. The method of claim 9, wherein the oxidizing is executed in a plasma enhanced chemical vapor deposition (PECVD) process.

19. The method of claim 9, wherein the oxidizing is executed in a plasma enhanced chemical vapor deposition (PECVD) process chamber having hydrogen (H₂).

20. A computing device comprising:
a circuit board; and
a die electrically coupled with the circuit board, the die including
a dielectric layer with a plurality of routing features; and
an etch stop layer, having a first interface region coupled with the dielectric layer and a second interface region disposed opposite to the first interface region;
wherein a profile of SiO₂ concentration levels in the first interface region and the second interface region is consistent with the etch stop layer being treated by a plasma treatment including carbon dioxide (CO₂) and nitrogen (N₂) from the second interface region.

21. The computing device of claim 20, wherein the first interface region has a peak silicon oxide (SiO₂) concentration level evenly distributed across the etch stop layer, and the second interface region has substantially zero silicon oxide (SiO₂) concentration level.

22. The computing device of claim 20, wherein a concentration of SiN at an outermost surface of the second interface region is a lowest concentration of SiN in the etch stop layer; and wherein the concentration of SiN increases continuously in the second region to a peak level and is substantially constant across the first region.

23. The computing device of claim 20, wherein:
the die is a processor; and
the computing device is a mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, and a camera.
